(19) United States
(12) Patent Application Publication
(10) Pub. No.: US 2026/0313777 A1
(43) Pub. Date: Oct. 8, 2026

(54) SUBSTRATE PROCESSING DEVICE AND SUBSTRATE PROCESSING METHOD

(71) Applicant: ULVAC, INC., Chigasaki-shi, Kanagawa (JP)

(72) Inventors: Teppei Takahashi, Chigasaki-shi, Kanagawa (JP); Ken Maehira, Chigasaki-shi, Kanagawa (JP)

(21) Appl. No.: 19/108,077

(22) PCT Filed: Feb. 14, 2024
(86) PCT No.: PCT/JP2024/005108

§ 371 Date: Feb. 28, 2025

(30) Foreign Application Priority Data
Feb. 17, 2023 (JP) 2023-023596

(51) Int. Cl. H05F 3/04; C23C 14/34

(52) U.S. Cl. CPC H05F 3/04; C23C 14/34

(57) ABSTRACT

A connection part of this substrate-processing device has an opening that connects a second space to a first space. In the substrate-processing device, a space that includes the first space and the second space connected to each other through the opening is a processing space. A static electricity elimination part is configured to generate plasma from a plasma generation gas supplied into a second vacuum tank, and eliminate static electricity from a support part positioned in the first space, by setting the average free path in the processing space for charged particles in the plasma to be shorter than the smallest dimension of the opening in a plane orthogonal to a plane along a direction from the second space toward the first space.

### TECHNICAL FIELD

The present disclosure relates to a substrate-processing device and a substrate-processing method.

### BACKGROUND ART

A device that neutralizes static electricity of a subject located in a vacuum container includes, for example, the vacuum container that accommodates the subject, and a ground electrode that closes an opening of the vacuum container. An insulating ring member is attached to the ground electrode. A filament and a mesh electrode are attached to the ring member. The filament attached to the ring member protrudes into a space surrounded by the ring member. The space surrounded by the ring member is located between the mesh electrode attached to the ring member and the ground electrode.

In a state in which current is supplied to the filament and voltage is applied to the mesh electrode, the static elimination device supplies gas into the space surrounded by the ring member and generates plasma. This neutralizes electric charge of the subject located in the vacuum chamber (e.g., refer to Patent Literature 1).

### CITATION LIST

### Patent Literature

Patent Literature 1: Japanese Laid-Open Patent Publication No. 2021-157909

### SUMMARY OF INVENTION

### Technical Problem

A cluster tool type device, which is an example of a substrate-processing device, includes a transfer chamber and processing chambers each connected to the transfer chamber via a gate valve. When one of the processing chambers is a sputtering chamber, for example, the sputtering chamber includes a target and a stage facing the target. Further, an electrostatic chuck is arranged on the stage to adsorb a substrate.

The above-described static elimination device may be set in a vacuum container in which a subject of static elimination is disposed. Accordingly, when the subject is a member located inside the sputtering chamber, members for plasma generation, such as a filament or a mesh electrode, may be installed in the sputtering chamber. However, various members for sputter deposition attached to the sputtering chamber may hinder the installation of the members for plasma generation in the sputtering chamber. Accordingly, there is a need for a configuration that generates plasma in a processing chamber, differing from a processing chamber in which a static elimination subject is disposed, and allows for static elimination of the subject using the generated plasma.

Such a problem is not limited to a cluster tool type device including a sputtering chamber, and may also be common in, for example, a film formation device including a processing chamber that performs film formation using a method other than sputtering, such as chemical vapor deposition (CVD), or a device that performs a process other than film formation and includes two or more vacuum containers.

### Solution to Problem

A substrate-processing device that solves the above problem includes a first vacuum container, a second vacuum container, a connector, and a static eliminator. The first vacuum container defines a first space that accommodates a static elimination subject. The second vacuum container defines a second space. The connector connects the second vacuum container to the first vacuum container. The static eliminator performs static elimination on the static elimination subject located in the first vacuum container. The connector includes an opening thorough which the second space is in communication with the first space. A space including the first space and the second space, which are in communication with each other through the opening, is a processing space. The static eliminator is configured to perform static elimination on the static elimination subject located in the first vacuum container by generating plasma from a plasma generation gas supplied to the second vacuum container so that charged particles in the plasma in the processing space have a mean free path that is shorter than a smallest dimension of the opening in a plane orthogonal to a plane extending in a direction from the second space toward the first space.

A substrate-processing method that solves the above problem includes connecting a second space, defined by a second vacuum container, to a first space, defined by a first vacuum container and accommodating a static elimination subject, through an opening in a connector that connects the second vacuum container to the first vacuum container; and performing static elimination on the static elimination subject located in the first space by generating plasma from a plasma generation gas supplied to the second vacuum container so that charged particles of the plasma in a processing space have a mean free path that is shorter than a smallest dimension of the opening in a plane orthogonal to a plane extending in a direction from the second space toward the first space, the processing space including the first space and the second space in communication with each other through the opening.

With the above substrate-processing device and substrate-processing method, the charged particles in the plasma easily move from the second space toward the first space. This readily reduces the electric potential of the static elimination subject, and also shortens the time required for static elimination of the static elimination subject.

In the above substrate-processing device, the static eliminator may adjust the mean free path of the charged particles by adjusting a pressure in the processing space so that the mean free path is shorter than the smallest dimension of the opening.

With the above substrate-processing device, the mean free path of the charged particles is inversely proportional to the pressure. This allows the mean free path of the charged particles to be readily changed by adjusting the pressure in the processing space.

In the above substrate-processing device, the static eliminator may adjust the pressure in the processing space by adjusting a flow rate of the plasma generation gas supplied to the processing space.

With the above substrate-processing device, the mean free path of the charged particles may be changed by simply varying the flow rate of the plasma generation gas supplied to the processing space. This facilitates adjustment of the mean free path.

In the above substrate-processing device, the plasma generation gas may be a noble gas.

With the above substrate-processing device, the charged particles in the plasma generated from a noble gas are likely to have a larger diameter than charged particles contained in plasma generated from other types of inert gas. Thus, the mean free path is readily reduced to be shorter than the dimension of the opening.

### BRIEF DESCRIPTION OF DRAWINGS

FIG. 1 is a schematic block diagram showing the structure of a cluster tool type sputtering device, which is an example of a substrate-processing device.

FIG. 2 is a schematic block diagram showing the structure of a transfer chamber and a first sputtering chamber of the sputtering device shown in FIG. 1.

FIG. 3 is a plan view showing an opening of a connector.

FIG. 4 is a plan view showing positions of charged plates arranged on a static elimination subject.

FIG. 5 is a graph illustrating a relationship between a voltage value of a positively charged plate and a time elapsed from initiation of a static elimination process.

FIG. 6 is a graph illustrating a relationship between a voltage value of a negatively charged plate and a time elapsed from initiation of a static elimination process.

FIG. 7 is a graph illustrating a relationship between a voltage value of a positively charged plate and a time elapsed from initiation of a static elimination process.

FIG. 8 is a graph illustrating a relationship between a voltage value of a negatively charged plate and a time elapsed from initiation of a static elimination process.

FIG. 9 is a diagram for illustrating an operation of the substrate-processing device.

FIG. 10 is a diagram illustrating an operation of the substrate-processing device.

### DESCRIPTION OF EMBODIMENTS

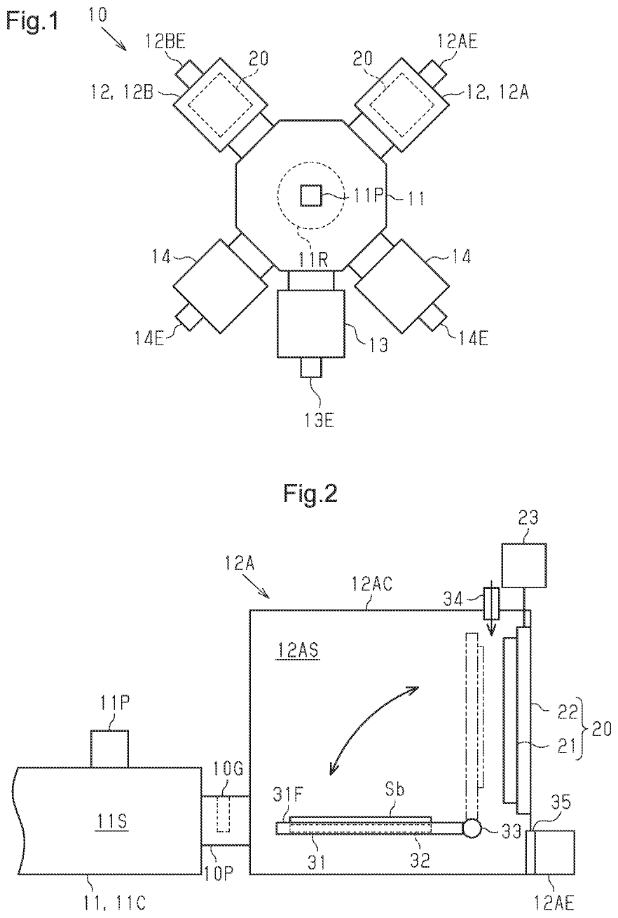

An embodiment of a substrate-processing device and a substrate-processing method will now be described with reference to FIGS. 1 to 10.

### Substrate-Processing Device

A substrate-processing device will be described with reference to FIGS. 1 to 3. Hereinafter, a cluster tool type sputtering device will be described as an example of a substrate-processing device.

As shown in FIG. 1, a cluster tool type sputtering device 10 includes a transfer chamber 11, two sputtering chambers 12, a loading chamber 13, and two substrate processing chambers 14. The sputtering device 10 includes the two sputtering chambers 12, namely, a first sputtering chamber 12A and a second sputtering chamber 12B.

The processing chambers 12A, 12B, 13, and 14 are connected to the transfer chamber 11. A gate valve is disposed between the transfer chamber 11 and each of the processing chambers 12A, 12B, 13, and 14. When the gate valve is open, a transfer space defined by the transfer chamber 11 is in communication with a processing space defined by a corresponding one of the processing chambers 12A, 12B, 13, and 14. When the gate valve is closed, the transfer space in the transfer chamber 11 is separated from the processing space in the corresponding one of the processing chambers 12A, 12B, 13, and 14.

The transfer chamber 11 includes a transfer robot 1R. The transfer robot 11R is configured to transfer a substrate between the transfer chamber 11 and the processing chambers connected to the transfer chamber 11. The transfer robot 11R transfers a substrate between the transfer chamber 11 and the processing chambers along a plane substantially parallel to the horizontal plane. The transfer chamber 11 includes a plasma generator 11P that generates plasma in the transfer space. The plasma generator 11P may be located, for example, in a central part of the transfer chamber 11 when the transfer chamber 11 is viewed from above.

The loading chamber 13 is configured to load an unprocessed substrate from outside the sputtering device 10 into the sputtering device 10, and unload a processed substrate from the sputtering device 10 to outside the sputtering device 10. The loading chamber 13 includes a exhaust unit 13E. When loading a substrate, a portal of the loading chamber 13 is opened in a state in which the loading chamber 13 is separated from the transfer chamber 11. This opens the loading chamber 13 to the atmosphere. An unprocessed substrate is loaded through the portal, and then the portal is closed. Subsequently, the exhaust unit 13E exhausts gas from the loading chamber 13 so as to depressurize the loading chamber 13 to a level approximately the same as the transfer chamber 11. Afterwards, the gate valve located between the loading chamber 13 and the transfer chamber 11 is opened.

When unloading a substrate, a processed substrate is transferred from the transfer chamber 11 into the loading chamber 13, and then the gate valve located between the loading chamber 13 and the transfer chamber 11 is closed. Subsequently, the pressure in the loading chamber 13 is raised to the atmospheric pressure, and then the portal of the loading chamber 13 is opened. The processed substrate is unloaded from the sputtering device 10 through the portal.

The sputtering chambers 12A and 12B each include a cathode 20. The sputtering chambers 12A and 12B are each configured to form a thin film on a surface of a substrate by performing sputtering using the cathode 20. The sputtering chambers 12A and 12B include exhaust units 12AE and 12BE that exhaust gas from the processing spaces defined by the sputtering chambers 12A and 12B.

Each of the substrate processing chambers 14 is configured to perform a predetermined process on a substrate. The process performed in the substrate processing chamber 14 may be pre-processing performed on a substrate before film formation in the sputtering chambers 12A and 12B or post-processing performed after film formation in the sputtering chambers 12A and 12B. The pre-processing or post-processing may be, for example, a heating process, a cooling process, or the like. Each of the substrate processing chambers 14 includes a exhaust unit 14E that exhausts gas from the processing space defined by the substrate processing chamber 14.

The transfer chamber 11 and the first sputtering chamber 12A will now be described in further detail with reference to FIG. 2. To facilitate illustration, in FIG. 2, the distance from the plasma generator 11P to the first sputtering chamber 12A is shorter than the distance from the plasma generator 11P to the first sputtering chamber 12A shown in FIG. 1.

As shown in FIG. 2, the transfer chamber 11 defines a transfer space 11S in which a substrate Sb is transferred. The first sputtering chamber 12A defines a first film formation space 12AS.

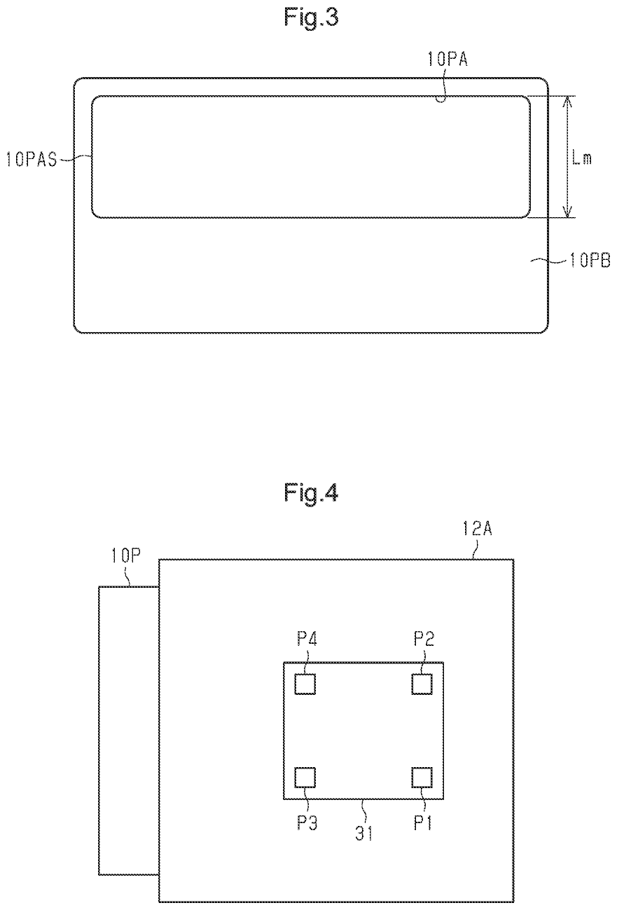

The sputtering device 10 includes a connector 10P that connects the transfer chamber 11 to the first sputtering chamber 12A. The connector 10P includes an opening 10PA (refer to FIG. 3) through which the transfer space 11S of the transfer chamber 11 is in communication with the first film formation space 12AS of the first sputtering chamber 12A. A gate valve 10G is disposed in the connector 10P. When the gate valve 10G is opened, the opening 10PA is open. Thus, the first film formation space 12AS is in communication with the transfer space 11S through the opening 10PA. When the gate valve 10G is closed, the opening 10PA is closed. Thus, the first film formation space 12AS is separated from the transfer space 11S. The connector 10P, which connects the transfer space 11S and the first film formation space 12AS through the opening 10PA, defines a space that is included in the processing space together with the transfer space 11S and the first film formation space 12AS.

The transfer chamber 11 includes a vacuum container 11C that defines the transfer space 11S. The vacuum container 11C is an example of a second vacuum container. The transfer space 11S is an example of a second space. As described above, the transfer chamber 11 includes the plasma generator 11P. The plasma generator 11P generates plasma from a plasma generation gas supplied to the transfer space 11S. The plasma generator 11P is, for example, a microwave plasma source.

The first sputtering chamber 12A includes a vacuum container 12AC that defines the first film formation space 12AS. The vacuum container 12AC is an example of a first vacuum container. The first film formation space 12AS is an example of a first space that accommodates a subject of static elimination. As described above, the first sputtering chamber 12A includes the cathode 20. The cathode 20 includes a target 21 and a backing plate 22. The target 21 is formed of, for example, a metal, a metal compound, or a mixture of a metal and a metal compound. The target 21 includes a surface that is sputtered during film formation on the substrate Sb. The backing plate 22 is joined to the target 21. The backing plate 22 is conductive. The cathode 20 is attached to a surface of one of the side walls that define the first film formation space 12AS. The cathode 20 exposes at least the sputtered surface of the target 21 to the first film formation space 12AS.

The backing plate 22 is connected to a target power supply 23. The voltage applied by the target power supply 23 to the backing plate 22 is applied to the target 21 connected to the backing plate 22. The target power supply 23 may be, for example, a direct current power supply or an alternating current power supply.

The first sputtering chamber 12A includes a support 31 and an adsorber 32. The support 31 is an example of a static elimination subject. The support 31 includes a support surface 31F that supports the substrate Sb. The support surface 31F may be formed of a material, for example, differing from a material forming a surface of the substrate Sb that contacts the support surface 31F. For example, the support surface 31F may be formed of aluminum oxide, and the substrate Sb may be a glass substrate. For example, the support 31 has the form of a flat plate, and the support surface 31F is a flat surface of the support 31.

The adsorber 32 is disposed in the support 31. The adsorber 32 electrostatically adsorbs the Sb substrate located on the support surface 31 to the support surface 31F. The adsorber 32 is an electrostatic chuck that adsorbs the substrate Sb using electrostatic force.

The first sputtering chamber 12A includes a position changer 33. The position changer 33 is configured to change the position of the support 31 relative to the cathode 20. The position changer 33 changes the position of the support 31 between a first position and a second position. When the support 31 is located at the first position, the support surface 31F is substantially perpendicular to the cathode 20. In other words, when the support 31 is located at the first position, the support surface 31F is substantially parallel to the horizontal direction. When the support 31 is located at the second position, the support surface 31F is substantially parallel to the cathode 20. In other words, when the support 31 is located at the second position, the support surface 31F is substantially parallel to the vertical direction.

The first sputtering chamber 12A further includes a gas inlet 34. The gas inlet 34 is a gas supply port of the vacuum container 12AC. The gas inlet 34 is connected to a gas cylinder located outside the sputtering device 10 via a mass flow controller. A plasma generation gas flows into the first film formation space 12AS through the gas inlet 34. The plasma generation gas is, for example, an inert gas. The inert gas may be a noble gas or a nitrogen gas. The noble gas may be, for example, argon gas or helium gas. Plasma generated from the plasma generation gas contains charged particles. In the present disclosure, charged particles refer to particles having electric charges other than electrons. For example, when argon gas is the plasma generation gas, positively charged argon ions are an example of the charged particles. When helium gas is the plasma generation gas, positively charged helium ions are an example of the charged particles.

The gas inlet 34 can include a conductance valve. The conductance valve sets a flow rate of the gas flowing through the gas inlet 34 into the first film formation space 12AS by adjusting an open amount of the valve. As the open amount of the conductance valve is changed from a first open amount to a second open amount, the flow rate of the gas flowing into the first film formation space 12AS changes from a first flow rate to a second flow rate.

When the support 31 is located at the second position such that the support surface 31F is substantially parallel to the vertical direction, for example, the gas inlet 34 may be located between the support 31 and the target 21 as viewed facing the horizontal plane. The gas inlet 34 may be located, for example, in an upper wall of the vacuum container 12AC. In this case, the gas flows through the gas inlet 34 into the first film formation space 12AS from an upper side to a lower side with respect to the vertical direction.

The vacuum container 12AC further includes a gas outlet 35 connected to the exhaust unit 12AE. The first sputtering chamber 12A may include a conductance valve between the gas outlet 35 and the exhaust unit 12AE. The conductance valve sets a flow rate of the exhausted gas by adjusting an open amount of the conductance valve. As the open amount of the conductance valve is changed from a first open amount to a second open amount, the exhausted gas flow rate changes from a first flow rate to a second flow rate.

When forming a film on the substrate Sb, the pressure in the first film formation space 12AS is adjusted to a predetermined pressure with the gas exhausted by the exhaust unit 12AE and the plasma generation gas supplied through the gas inlet 34. The pressure in the first film formation space 12AS may be, for example, in a range of 1×10⁻¹ Pa to 1×10¹ Pa, inclusive. The pressure in the first film formation space 12AS during film formation may be the same as the pressure in the first film formation space 12AS during static elimination in the first sputtering chamber 12A.

When performing static elimination on the support 31, the pressure in the first film formation space 12AS is adjusted to a predetermined pressure with the gas exhausted by the exhaust unit 12AE and the plasma generation gas supplied through the gas inlet 34. When performing static elimination on the support 31, the gate valve 10G is opened such that the opening 10PA is open. Thus, the pressure in the first film formation space 12AS is substantially equal to the pressure in the transfer space 11S. Therefore, the pressure in the processing space, including the first film formation space 12AS and the transfer space 11S, is substantially uniform. Accordingly, it can be understood that the charged particles in the first film formation space 12AS have a mean free path that is equal to the mean free path of the charged particles in the transfer space 11S and to the mean free path of the charged particles in the processing space. During static elimination of the support 31, the pressure in the first film formation space 12AS may be, for example, in a range of 1×10⁻¹ Pa to 1×10¹ Pa, inclusive.

FIG. 3 shows the planar structure of the opening 10PA included in the connector 10P. FIG. 3 shows the structure of the opening 10PA in a plane orthogonal to a plane extending in a direction from the transfer chamber 11 toward the first sputtering chamber 12A. Specifically, FIG. 3 shows the structure of the opening 10PA in a plane orthogonal to a plane extending in a direction in which the connector 10P, which connects the transfer chamber 11 to the first sputtering chamber 12A, extends. The connector 10P shown in FIGS. 1 and 2 is tubular and extends in a direction from the transfer chamber 11 toward the first sputtering chamber 12A. Thus, the inner surface of the connector 10P defines a passage for the transfer robot 11R that carries the substrate Sb.

A plate member 10PB shown in FIG. 3 is disposed in the passage defined by the connector 10P. The plate member 10PB includes the opening 10PA. The outer edge of the plate member 10PB is in contact with the inner surface of the connector 10P. This seals the passage defined by the connector 10P except for the opening 10PA in a plane including the plate member 10PB. Thus, the transfer space 11S is in communication with the first film formation space 12AS through the opening 10PA.

In the present embodiment, the opening 10PA is rectangular. In the example shown in FIG. 3, four corners of the opening 10PA each have a curvature such that the center of curvature is located within the opening 10PA. Since the opening OPA is rectangular, the dimension of a short side 10PAS of the opening 10PA corresponds to a smallest dimension Lm of the opening 10PA. The opening 10PA does not have to be rectangular. The opening 10PA may have, for example, a polygonal shape other than a rectangle. Examples of the polygonal shape other than a rectangle include a square, a diamond shape, or a hexagon. The opening 10PA may be circular.

The smallest dimension of the opening 10PA refers to the length of a line segment extending through the geometric center of the outer edge of the opening 10PA and connecting a first point and a second point on the outer edge. Thus, when the opening 10PA is square, for example, the smallest dimension of the opening 10PA is the length of a line segment extending through the geometric center of the outer edge of the opening 10PA and connecting two parallel sides of the outer edge. Furthermore, when the opening 10PA is circular, the smallest dimension of the opening 10PA is the length of a line segment extending through the geometric center of the outer edge of the opening 10PA and connecting two points on the circumference, that is, the diameter of the circle.

In the sputtering device 10 of the present embodiment, a static eliminator generates plasma from the plasma generation gas supplied to the transfer chamber 11. In this case, the mean free path of the charged particles in the plasma in the processing space is shorter than the smallest dimension Lm of the opening 10PA so that static electricity of the support 31 located in the first film formation space 12AS is neutralized. Thus, the charged particles in the plasma easily move from the transfer space 11S toward the first film formation space 12AS. This readily reduces the electric potential of the support 31, that is, an absolute value of the electric potential of the support 31, and also shortens the time required for static elimination of the support 31. As a result, static elimination of the support 31 is facilitated.

The mean free path λ of the charged particles is calculated by the following Equation (1).

$$Expression 1$$

$$λ = \frac{1}{π \cdot \sqrt{2} \cdot n \cdot {( 2 r )}^{2}} \qquad Equation ( 1 )$$

In Equation (1), “2r” represents the diameter of the charged particles, and “n” represents the particle number density. Thus, the mean free path is inversely proportional to the pressure in accordance with the following Equation (2).

$$Expression 2$$

$$ρ = n \cdot k \cdot T \qquad Equation ( 2 )$$

In Equation (2), “p” represents the pressure, “n” represents the particle number density, “k” represents the Boltzmann constant, and “T” represents the thermodynamic temperature.

The static eliminator may adjust the mean free path of the charged particles by adjusting the pressure in the processing space so that the mean free path is shorter than the smallest dimension Lm of the opening 10PA. As apparent from Equations (1) and (2), the mean free path of charged particles is inversely proportional to the pressure. This allows the mean free path of charged particles to be readily changed by adjusting the pressure in the processing space.

The static eliminator may adjust the pressure in the processing space by adjusting the flow rate of the plasma generation gas supplied to the processing space. In this case, the mean free path of the charged particles may be changed by simply varying the flow rate of the plasma generation gas supplied to the processing space. This facilitates adjustment of the mean free path.

The plasma generation gas may be a noble gas. In the plasma generated from a noble gas, the charged particles are likely to have a larger diameter than charged particles contained in plasma generated from other types of inert gas. Thus, the mean free path is readily reduced to be shorter than the dimension of the opening 10PA.

### Substrate-Processing Method

The substrate-processing method of the present embodiment includes connecting the first film formation space 12AS to the transfer space 11S and performing static elimination on the support 31 located in the first film formation space 12AS. The connecting the first film formation space 12AS to the transfer space 11S includes connecting the transfer space 11S to the first film formation space 12AS through the opening 10PA of the connector 10P. The performing static elimination on the support 31 includes generating plasma from the plasma generation gas supplied to the transfer chamber 11 so that the mean free path of the charged particles in the plasma in the processing space is shorter than the smallest dimension of the opening 10PA. The substrate-processing method in accordance with the present embodiment will now be described in more detail.

When performing static elimination on the support 31, the gate valve 10G is opened in a state in which the first film formation space 12AS is depressurized to a predetermined pressure by the exhaust unit 12AE of the first sputtering chamber 12A. This opens the opening 10PA so that the transfer space 11S, defined by the transfer chamber 11, is also depressurized by the exhaust unit 12AE together with the first film formation space 12AS. When a predetermined period elapses from the opening of the gate valve 10G, the plasma generation gas is introduced through the gas inlet 34 into the first film formation space 12AS. Preferably, a time point at which introduction of the plasma generation gas into the first film formation space 12AS is initiated is set to be after a period in which the transfer space 11S is depressurized to a level approximately equal to that of the first film formation space 12AS. As the plasma generation gas flows into the first film formation space 12AS, the plasma generation gas is also introduced to the transfer space 11S through the opening 10PA.

When a predetermined period elapses from the initiation of introduction of the plasma generation gas, microwave power is supplied to the plasma generator 11P so that plasma is generated from the plasma generation gas in the transfer space 11S. The charged particles in the plasma are supplied from the transfer space 11S through the opening 10PA to the first film formation space 12AS. This neutralizes static electricity of the support 31, which is a static elimination subject. That is, in the sputtering device 10 of the present embodiment, the static eliminator that performs static elimination of the support 31 located in the first film formation space 12AS includes the gas inlet 34, the exhaust unit 12AE, and the plasma generator 11P.

Static elimination of the support 31 is performed during a period in which the substrate Sb is not electrostatically adsorbed relative to the support 31. Thus, static elimination of the support 31 is performed between a film forming process on a first substrate Sb and a film forming process on a second substrate Sb. Static elimination of the support 31 may be performed each time a film formation process is performed on a single substrate Sb or each time a film formation process is performed on multiple substrates Sb.

### EXPERIMENTAL EXAMPLES

Experimental examples will now be described with reference to FIGS. 4 to 10.

FIG. 4 is a plan view showing positions of charged plates arranged on the support 31.

As shown in FIG. 4, in Experimental Examples 1 to 3, a single charged plate was arranged at each of four corners of the quadrangular support 31. A third plate P3 and a fourth plate P4 were respectively arranged at two of the four corners of the support 31 that were relatively close to the transfer chamber 11 in a direction from the transfer chamber 11 toward the first sputtering chamber 12A. Further, a first plate P1 and a second plate P2 were respectively arranged at the other two of the four corners of the support 31 that were relatively far from the transfer chamber 11 in the direction from the transfer chamber 11 toward the first sputtering chamber 12A.

Thus, the first plate P1 and the second plate P2 had substantially the same distance from the plasma generator 11P, and the third plate P3 and the fourth plate P4 had substantially the same distance from the plasma generator 11P. The distance between the plasma generator 11P and the first plate P1 was 3750 mm, and the distance between the plasma generator 11P and the second plate P2 was 3820 mm. The distance between the plasma generator 11P and the third plate P3 was 2850 mm, and the distance between the plasma generator 11P and the fourth plate P4 was 2940 mm.

### Experimental Example 1

The cluster tool sputtering device 10 generated plasma in the processing space in a state in which the opening 10PA was open. The conditions for plasma generation were set as follows.
Pressure of Processing Space: 6.8×10⁻² Pa
Plasma Generation Gas: Argon Gas
Flow Rate of Plasma Generation Gas: 11.12 sccm
Mean Free Path: 105 mm
Minimum Dimension of Opening 10PA: 250 mm

### Experimental Example 2

In Experimental Example 2, the pressure in the processing space and the mean free path among the plasma generation conditions in Experimental Example 1 were changed as follows. Further, the flow rate of the plasma generation gas was set as follows. In this case, the open amount of the conductance valve between the gas outlet and the exhaust unit was changed from that of Experimental Example 1. Except for the above, plasma was generated under the same conditions as in Experimental Example 1.
Pressure of Processing Space: 1.1×10⁻² Pa
Flow Rate of Plasma Generation Gas: 11.12 sccm
Mean Free Path: 650 mm

### Experimental Example 3

In Experimental Example 3, the pressure in the processing space and the mean free path among the plasma generation conditions in Experimental Example 1 were changed as follows. Further, the flow rate of the plasma generation gas was set as follows. In this case, the open amount of the conductance valve between the gas outlet and the exhaust unit was changed from that of Experimental Example 1. Except for the above, plasma was generated under the same conditions as in Experimental Example 1.
Pressure of Processing Space: 6.1×10⁻³ Pa
Flow Rate of Plasma Generation Gas: 11.12 sccm
Mean Free Path: 1170 mm

### Evaluation Method and Evaluation Result

In each Experimental Example, plasma was generated in the processing space with an initial voltage value of each of the charged plates set to approximately +1.2 V. Then, temporal changes in the voltage value of the charged plates were measured from the initiation of plasma generation. Also, plasma was generated in the processing space with the initial voltage value of each of the charged plates set to approximately −1.2 V. Then, temporal changes in the voltage value of the charged plates were measured from the initiation of plasma generation.

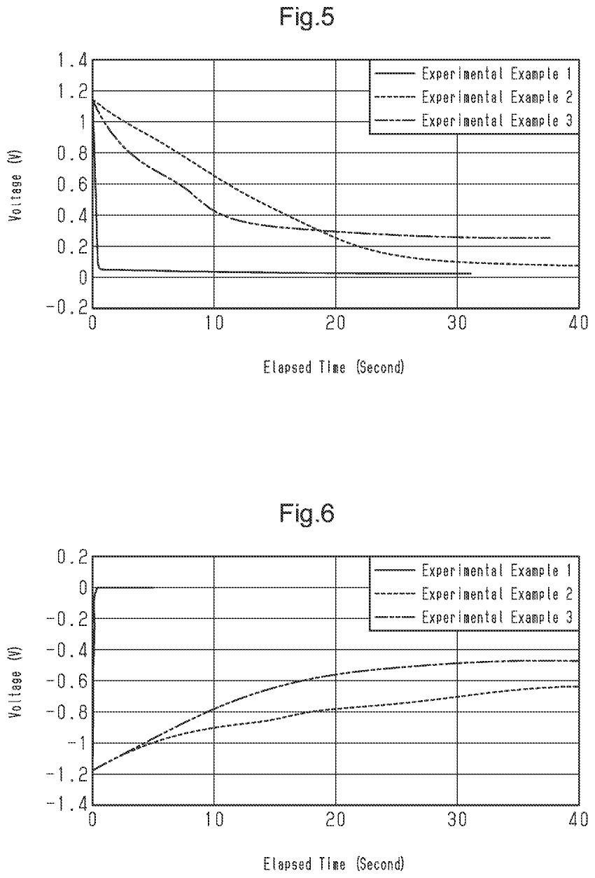

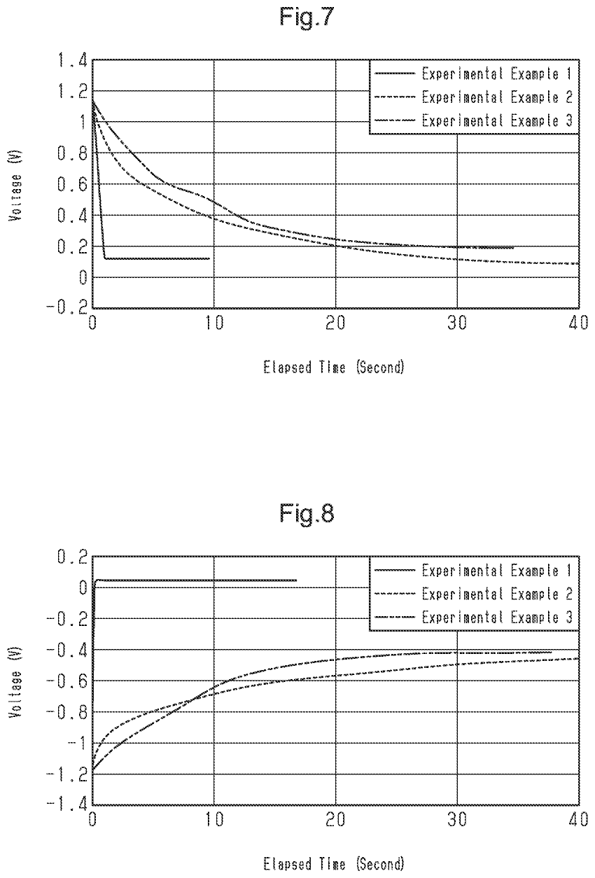

FIG. 5 shows the temporal change in the voltage value when the initial voltage value of the first plate P1 was set to approximately +1.2 V. FIG. 6 shows the temporal change in the voltage value when the initial voltage value of the first plate P1 was set to approximately −1.2 V. FIG. 7 shows the temporal change in the voltage value when the initial voltage value of the fourth plate P4 was set to approximately +1.2 V. FIG. 8 shows the temporal change in the voltage value when the initial voltage value of the fourth plate P4 was set to approximately −1.2 V.

As shown in FIGS. 5 and 6, regardless of whether the initial voltage value of the first plate P1 was positive or negative in Experimental Example 1, as plasma generation was initiated, the voltage value of the first plate P1 steeply approached 0 V during a period in which the time elapsed from the initiation was less than one second. In contrast, regardless of whether the initial voltage value of the first plate P1 was positive or negative in Experimental Examples 2 and 3, the voltage value of the first plate P1 had a lower change rate. Further, in Experimental Examples 2 and 3, when approximately thirty seconds elapsed from the initiation of plasma generation, the voltage value of the first plate P1 stopped changing without the voltage value of the first plate P1 reaching 0 V. In Experimental Examples 2 and 3, when the initial voltage value of the first plate P1 was negative, the voltage value of the first plate P1 stopped changing in a state in which a deviation amount of the voltage value of the first plate P1 from 0 V was relatively large.

As shown in FIGS. 7 and 8, regardless of whether the initial voltage value of the fourth plate P4 was positive or negative in Experimental Example 1, as plasma generation was initiated, the voltage value of the first plate P1 steeply approached 0 V during a period in which the time elapsed from the initiation was approximately one second. However, a deviation amount of the voltage value of the fourth plate P4 from 0 V was greater than the deviation amount of the voltage value of the first plate P1 from 0V. In contrast, regardless of whether the initial voltage value of the fourth plate P4 was positive or negative in Experimental Examples 2 and 3, the voltage value of the fourth plate P4 had a lower change rate. Further, when the initial voltage value of the fourth plate P4 was negative in Experimental Examples 2 and 3, the voltage value of the fourth plate P4 stopped changing as approximately twenty seconds elapsed from the initiation of plasma generation. In this case, the voltage value of the fourth plate P4 did not reach 0 V. In addition, in Experimental Examples 2 and 3, the voltage value of the fourth plate P4 stopped changing in a state in which the deviation amount of the voltage value of the fourth plate P4 from 0 V was relatively large.

In this manner, when the mean free path of the charged particles was longer than the smallest dimension of the opening 10PA; particularly, when the initial voltage value of the charged plate was negative, static elimination of the charged plate was limited. In contrast, when the mean free path of the charged particles was shorter than the smallest dimension of the opening 10PA, regardless of whether the initial voltage value of the charged plate was negative or positive, the static elimination was equivalent. This indicates that a difference between the electron mobility and the ion mobility was mitigated. Also, the effect of the mean free path of the charged particles being less than the minimum dimension of the opening 10PA was significant when the initial voltage value of the charged plate was negative; that is, when static elimination was performed using ions.

The temporal change in the voltage value of the second plate P2 had a similar trend to that of the first plate P1. Also, the temporal change in the voltage value of the third plate P3 had a similar trend to that of the fourth plate P4.

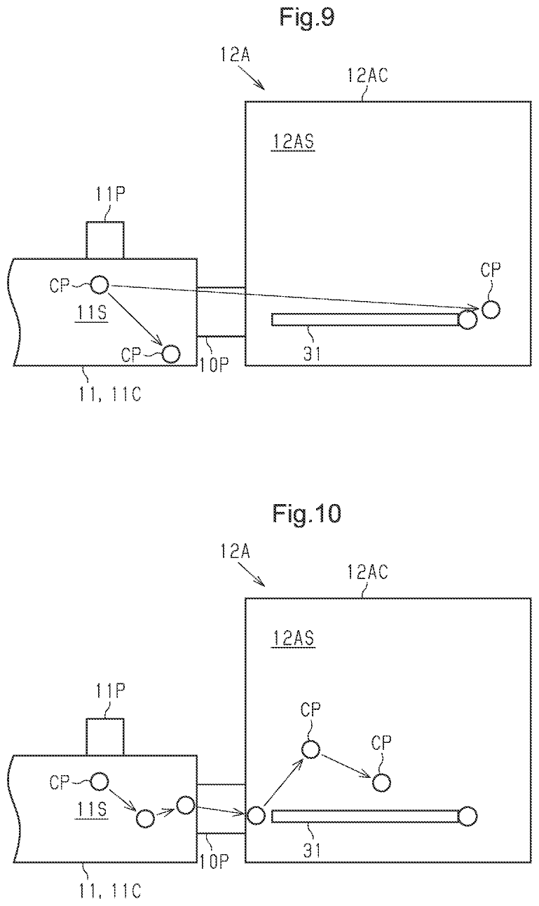

The operation of the substrate-processing device will now be described with reference to FIGS. 9 and 10. FIG. 9 shows estimated behaviors of the charged particles when the mean free path of the charged particles is longer than the smallest dimension Lm of the opening 10PA. FIG. 10 shows estimated behaviors of the charged particles when the mean free path of the charged particle is shorter than the smallest dimension Lm of the opening 10PA.

As shown in FIG. 9, when the mean free path of the charged particles CP is longer than or equal to the smallest dimension Lm of the opening 10PA, the charged particles CP are less likely to collide with other particles present in the processing space before and after passing through the opening 10PA. Accordingly, the trajectories of the charged particles CP are likely to stay the same. As a result, the charged particles CP that reach the support 31 are limited.

In contrast, as shown in FIG. 10, when the mean free path of the charged particles CP is shorter than the smallest dimension Lm of the opening 10PA, the charged particles CP are more likely to collide with other particles present in the processing space before and after passing through the opening 10PA. Accordingly, the trajectories of the charged particle CP are likely to change. As a result, a higher percentage of the charged particles CP will reach the support 31.

As described above, the substrate-processing device and the substrate-processing method in accordance with the embodiment have the following advantages.
(1) The charged particles CP in the plasma easily move from the transfer space 11S toward the first film formation space 12AS. This readily reduces the electric potential of the support 31, and also shortens the time required for static elimination of the support 31.
(2) The mean free path of the charged particles CP is inversely proportional to the pressure. This allows the mean free path of the charged particles CP to be readily changed by adjusting the pressure in the processing space.
(3) The mean free path of the charged particles may be changed by simply varying the flow rate of the plasma generation gas supplied to the processing space. This facilitates adjustment of the mean free path.
(4) The charged particles in the plasma generated from a noble gas are likely to have a larger diameter than charged particles contained in plasma generated from other types of inert gas. Thus, the mean free path is readily reduced to be shorter than the dimension of the opening 10PA.

The above embodiment may be changed as described below.

### Static Eliminator

The mean free path of the charged particles may be changed from a first value to a second value by varying at least one of the flow rate of plasma generation gas, the type of plasma generation gas, the open amount of the conductance valve between the gas outlet 35 and the exhaust unit 12AE, and the flow rate of gas exhausted by in the exhaust unit 12AE. In other words, the mean free path of charged particles may be adjusted with one or more of the flow rate of plasma generation gas, the type of plasma generation gas, the open amount of the conductance valve between the gas outlet 35 and the exhaust unit 12AE, and the flow rate of gas exhausted by the exhaust unit 12AE.

### Sputtering Device

The sputtering device may include a plurality of processing chambers arranged next to one another in a single direction. Further, the sputtering device may be configured to transfer a substrate, which is a processing subject, within the sputtering device along a plane substantially parallel to the vertical plane. Even in this case, same advantage as advantage (1) may be obtained when plasma for static elimination is generated so that the mean free path of charged particles is shorter than the smallest dimension of the opening, which is located between the second vacuum container and the first vacuum container in which the plasma for static elimination is generated.

### Substrate-Processing Device

The substrate-processing device of the present disclosure may be a film formation device other than a sputtering device. The substrate-processing device may be, for example, a chemical vapor deposition (CVD) device. Alternatively, the substrate-processing device of the present disclosure may be a substrate-processing device that performs a process other than film formation on a substrate. The substrate-processing device may be, for example, an etching device.

### REFERENCE SIGNS LIST

10) sputtering device
11) transfer chamber
12) sputtering chamber
12A) first sputtering chamber
12B) second sputtering chamber

1. A substrate-processing device, comprising:
a first vacuum container defining a first space that accommodates a static elimination subject;
a second vacuum container defining a second space;
a connector connecting the second vacuum container to the first vacuum container; and
a static eliminator that performs static elimination on the static elimination subject located in the first vacuum container, wherein:
the connector includes an opening thorough which the second space is in communication with the first space;
a space including the first space and the second space, which are in communication with each other through the opening, is a processing space; and
the static eliminator is configured to perform static elimination on the static elimination subject located in the first vacuum container by generating plasma from a plasma generation gas supplied to the second vacuum container so that charged particles in the plasma in the processing space have a mean free path that is shorter than a smallest dimension of the opening in a plane orthogonal to a plane extending in a direction from the second space toward the first space.

2. The substrate-processing device according to claim 1, wherein the static eliminator adjusts the mean free path of the charged particles by adjusting a pressure in the processing space so that the mean free path is shorter than the smallest dimension of the opening.

3. The substrate-processing device according to claim 2, wherein the static eliminator adjusts the pressure in the processing space by adjusting a flow rate of the plasma generation gas supplied to the processing space.

4. The substrate-processing device according to claim 1, wherein the plasma generation gas is a noble gas.

5. A substrate-processing method, comprising:
connecting a second space, defined by a second vacuum container, to a first space, defined by a first vacuum container and accommodating a static elimination subject, through an opening in a connector that connects the second vacuum container to the first vacuum container; and
performing static elimination on the static elimination subject located in the first space by generating plasma from a plasma generation gas supplied to the second vacuum container so that charged particles of the plasma in a processing space have a mean free path that is shorter than a smallest dimension of the opening in a plane orthogonal to a plane extending in a direction from the second space toward the first space, the processing space including the first space and the second space in communication with each other through the opening.
